(19) United States
(12) Patent Application Publication
(10) Pub. No.: US 2016/0019967 A1
(43) Pub. Date: Jan. 21, 2016

(54) EXTERNAL MEMORY DEVICE

(71) Applicant: SAMSUNG ELECTRONICS CO., LTD., Suwon-si (KR)

(72) Inventors: Myungryul JANG, Suwon-si (KR); Sung-ki LEE, Hwaseong-si (KR); Jongmin JANG, Suwon-si (KR)

(73) Assignee: SAMSUNG ELECTRONICS CO., LTD., Suwon-si (KR)

(21) Appl. No.: 14/802,605

(22) Filed: Jul. 17, 2015

(30) Foreign Application Priority Data
Jul. 18, 2014 (KR) 10-2014-0091228

(51) Int. Cl. G11C 16/10; G06F 1/16; G06F 12/02

(52) U.S. Cl. CPC G11C 16/102; G06F 12/0238; G06F 1/1632; G06F 2212/202

(57) ABSTRACT

An external memory device configured to communicate with an external electronic device includes: a semiconductor substrate including a first edge and a second edge perpendicular to the first edge; a semiconductor integrated circuit device provided on the semiconductor substrate, the semiconductor integrated circuit device including a memory device configured to store data provided from the external electronic device, an input/output interface configured to interface with the external electronic device, and a controller configured to control the memory device in response to a signal transmitted through the input/output interface; an insulating layer covering the semiconductor integrated circuit device; and external input/output pins provided adjacent to the first edge on the insulating layer and configured to establish an electrical connection between the external electronic device and the semiconductor integrated circuit device.

### CROSS-REFERENCE TO RELATED APPLICATION

This application claims priority under 35 U.S.C. §119 to Korean Patent Application No. 10-2014-0091228, filed on Jul. 18, 2014, the entire contents of which are hereby incorporated by reference in their entirety.

### TECHNICAL FIELD

The exemplary embodiments relate to an external memory device configured to communicate with an electronic device, and more particularly, to a solid state drive manufactured at a wafer level.

### DESCRIPTION OF THE RELATED ART

With the advent of recently developed information technology, the amount of personal data to be stored and transferred has risen explosively. Due to the increasing demand for such information, various kinds of personal external storage devices are under development. An external storage device is configured with a single storage device, communicates with a host device, and also stores or reads data in response to a command of the host device.

Among extended storage devices, hard disk drives (HDDs) are widely used due to advantages such as high recording density, high data transfer rate, fast data access time, and low price. The HDDs are configured with a platter and complex mechanical components for driving the platter. Therefore, failures may occur in the HDDs due to small shocks and vibration.

Recently, memory devices using non-volatile semiconductor devices, for example, solid state drives (SSDs), have begun replacing the HDDs more and more. Accordingly, SSDs need to be developed at low costs within a shorter period of time.

### SUMMARY

Exemplary embodiments provide an external memory device of a wafer level that is configured to communicate with an electronic device.

Exemplary embodiments also provide a method of fabricating an external memory device configured to communicate with an electronic device.

According to an aspect of an exemplary embodiment, there is provided an external memory device configured to communicate with an external electronic device. The external memory device may include: a semiconductor substrate including a first edge and a second edge perpendicular to the first edge; a semiconductor integrated circuit device provided on the semiconductor substrate and including a memory device configured to store data provided from the external electronic device, an input/output interface configured to interface with the external electronic device, and a controller configured to control the memory device in response to a signal transmitted through the input/output interface; an insulating layer covering the semiconductor integrated circuit device; and external input/output pins provided adjacent to the first edge on the insulating layer and configured to establish an electrical connection between the external electronic device and the semiconductor integrated circuit device.

The external memory device may further include: interconnections connecting the external input/output pins to the semiconductor integrated circuit device, the interconnections being provided on the insulating layer; and a passivation layer covering the interconnections provided on the insulating layer and exposing portions of the external input/output pins to enable the external input/output pins to directly connect to the external electronic device.

The external memory device may further include through electrodes penetrating the semiconductor substrate and the insulating layer to connect the interconnections and the semiconductor integrated circuit device.

The external input/output pins and the interconnections may be provided on a top surface of the insulating layer and a thickness of the external input/output pins may be greater than a thickness of the interconnections.

The external input/output pins may include a metallic material different from a metallic material of the interconnections.

The semiconductor substrate may be a silicon substrate, a germanium substrate, a silicon-germanium substrate, a silicon on insulator (SOI) substrate, a germanium on insulator (GOI) substrate, or a semiconductor epitaxial substrate.

The external input/output pins may include power input pins into which power is inputted from the external electronic device and signal input/output pins through which electrical signals are inputted from or outputted to the external electronic device.

The external input/output pins may be configured to exchange data with the external electronic device in a serial advanced technology attachment (ATA) scheme.

According to another aspect of an exemplary embodiment, there is provided an external memory may include: a substrate; a semiconductor integrated circuit (IC) provided on the substrate; a passivation layer covering a portion of the semiconductor IC; and an external pin provided adjacent to a side of the passivation layer, the external pin being exposed to an outside of the external memory and configured to establish an electrical connection between the semiconductor IC and an external electronic device. Here, the external pin physically contacts the external electronic device.

The external pin may include a first metal layer and a second metal layer on the first metal layer. The second metal layer may be exposed to the outside of the external memory.

The second metal layer may comprise noble metals.

The substrate may comprise a single-crystal semiconductor material.

The semiconductor IC may include: a memory device configured to store data provided from the external electronic device; an input/output interface configured to interface with the external electronic device; and a controller configured to control the memory device in response to a signal transmitted through the input/output interface.

The external memory may further include a redistribution pattern comprising a first end connected to the external pin; and a through electrode connected to a second end of the redistribution pattern and further connected to the semiconductor IC.

The external pin may include power input pins into which power is inputted from the external electronic device and signal input/output pins through which electrical signals are inputted from or outputted to the external electronic device.

### BRIEF DESCRIPTION OF THE DRAWINGS

The accompanying drawings are included to provide a further understanding of the exemplary embodiments, and are incorporated in and constitute a part of this specification. The drawings illustrate exemplary embodiments and, together with the description, serve to explain principles of the exemplary embodiments. In the drawings:

FIG. 1 is a perspective view of an external memory device according to an exemplary embodiment;

FIG. 2 is a plan view of an external memory device according to an exemplary embodiment;

FIG. 3 is a schematic sectional view of an external memory device according to an exemplary embodiment;

FIG. 4 is a sectional view of an external memory device according to an exemplary embodiment;

FIGS. 5 and 6 are block diagrams of a semiconductor integrated circuit device integrated into an external memory device according to an exemplary embodiment;

FIG. 7 is a plan view of an external memory device according to another exemplary embodiment;

FIG. 8 is a sectional view of an external memory device according to another exemplary embodiment;

FIG. 9 is a perspective view of an external memory device according to another exemplary embodiment;

FIG. 10 is a schematic sectional view of an external memory device according to another exemplary embodiment;

FIGS. 11 and 12 are sectional views of an external memory device according to various exemplary embodiments;

FIG. 13 is a flowchart illustrating a method of fabricating an external memory device according to an exemplary embodiment;

FIGS. 14 to 16 are views illustrating a method of fabricating an external memory device according to an exemplary embodiment;

FIG. 17 is a block diagram illustrating a connection between an external memory device and an electronic device according to an exemplary embodiment;

FIGS. 18 and 19 are views illustrating a connection between an external memory device and an electronic device according to exemplary embodiments;

FIGS. 20 and 21 are views illustrating electronic devices to which an external memory device may be applied according to exemplary embodiments; and

FIG. 22 is a block diagram of an electronic system including an external memory device according to an exemplary embodiment.

### DETAILED DESCRIPTION OF THE EXEMPLARY EMBODIMENTS

Exemplary embodiments will be described in detail with reference to the accompanying drawings. The exemplary embodiments, however, may be embodied in various different forms, and should not be construed as being limited only to the illustrated exemplary embodiments. Rather, these exemplary embodiments are provided as examples so that this disclosure will be thorough and complete, and will fully convey the concepts of the disclosure to those skilled in the art. Accordingly, known processes, elements, and techniques are not described with respect to some of the exemplary embodiments. Unless otherwise noted, like reference numerals denote like elements throughout the attached drawings and written description, and thus, descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the exemplary embodiment.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, the layer can be the only layer between the two layers, or one or more intervening layers may also be present.

The terminology used herein is for the purpose of describing particular exemplary embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, the element or layer can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Hereinafter, an external memory device according to exemplary embodiments will be described in more detail with reference to the accompanying drawings.

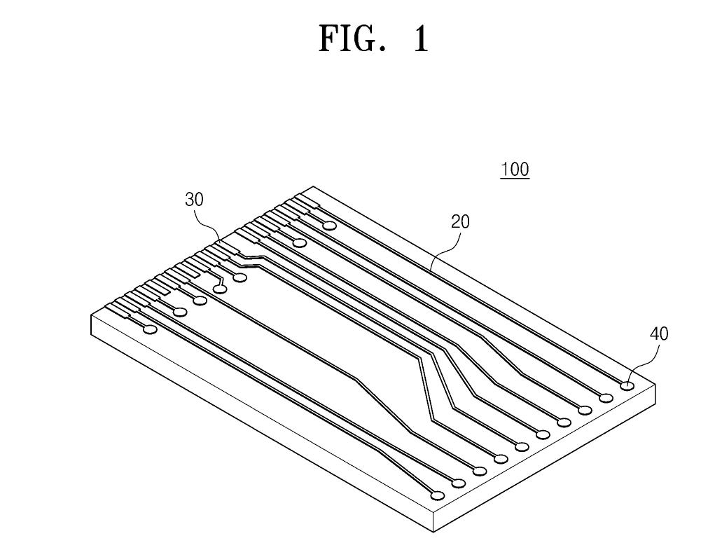

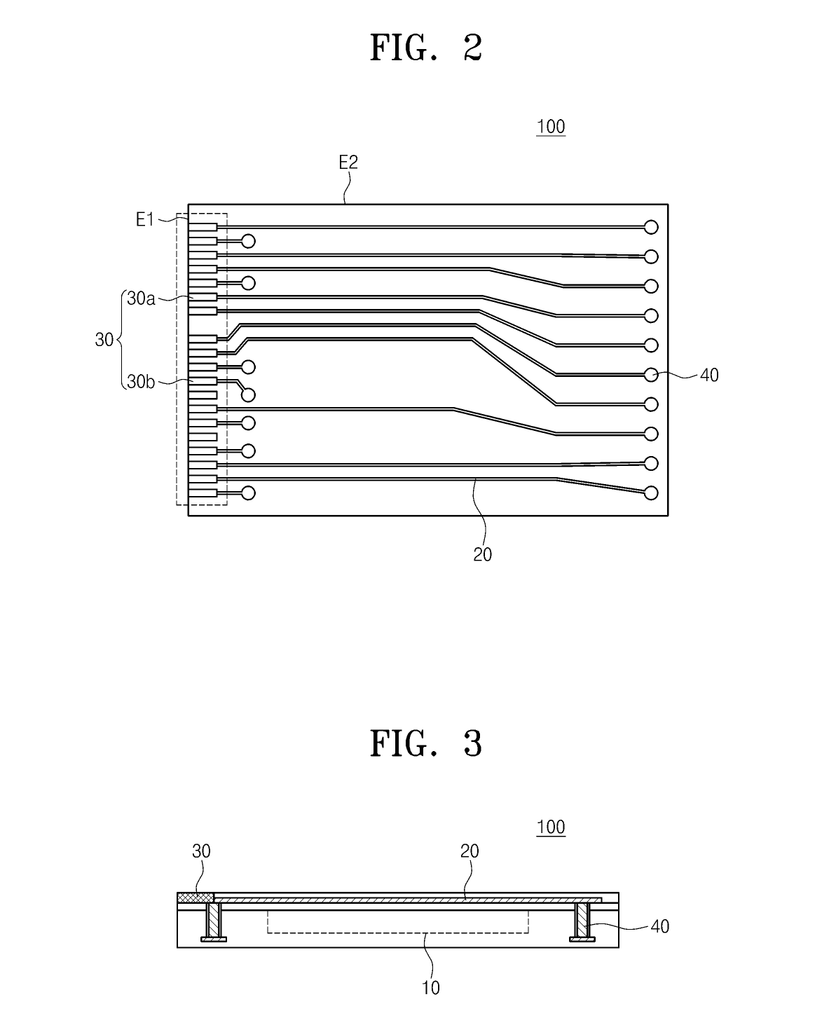

FIG. 1 is a perspective view of an external memory device according to an exemplary embodiment. FIG. 2 is a plan view of an external memory device according to an exemplary embodiment. FIG. 3 is a schematic sectional view of an external memory device according to an exemplary embodiment.

Referring to FIGS. 1, 2, and 3, an external memory device 100 includes a semiconductor integrated circuit (IC) device 10, redistribution patterns 20 connected to the semiconductor IC device 10, and external input/output pins 30 connected to ends of the redistribution patterns 20.

The semiconductor IC device 10 may be formed on a semiconductor substrate and may constitute various logic circuits. For example, the semiconductor IC device 10 may be a memory device such as DRAM, NAND flash, NOR flash, OneNAND, PRAM, ReRAM, or MRAM. As another example, the semiconductor IC device 10 may be a logic device such as an optical electronic device, a communication device, a digital signal processor, a controller, or a system-on-chip. As another example, the semiconductor IC device 10 may include a memory device and a logic device controlling the memory device.

The redistribution patterns 20 may be connected to the semiconductor IC device 10 through internal interconnections 40.

The external input/output pins 30 may provide an electrical connection between an external electronic device and an external memory device. According to an exemplary embodiment, the external input/output pins 30 may be electrically connected to the semiconductor IC device 10 through the redistribution patterns 20 and the internal interconnections 40. The external input/output pins 30 may include power input pins 30a through which power from an external electronic device is inputted and signal input/output pins 30b through which electrical signals from an external electronic device are inputted/outputted. Accordingly, signals provided from an external electronic device may be provided to the semiconductor IC device 10 through the external input/output pins 30.

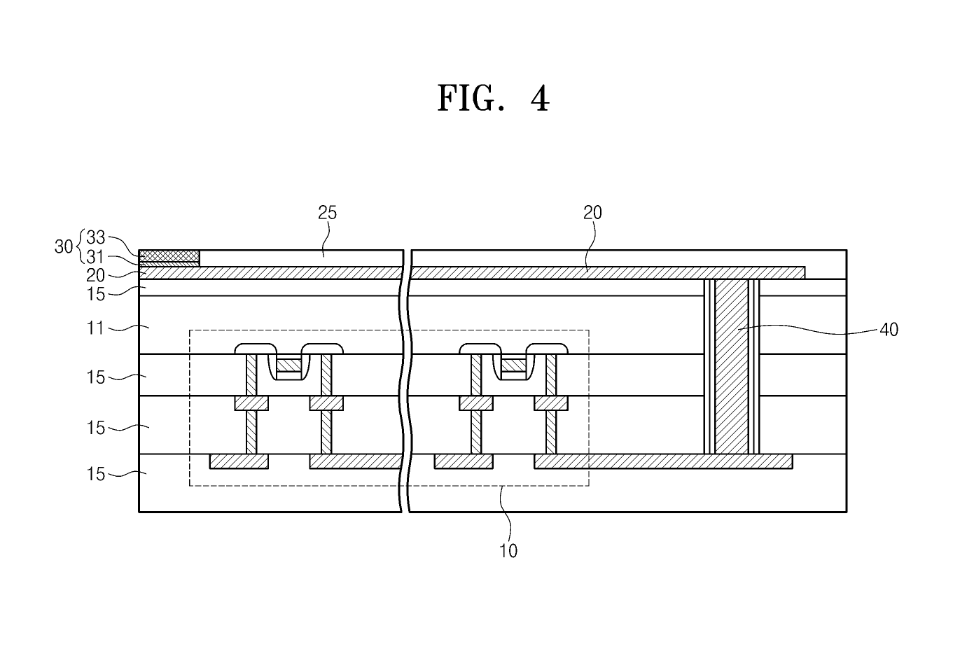

According to an exemplary embodiment, the external memory device 100 may include a first edge E1 and a second edge E2 perpendicular to each other and the external input/output pins 30 may be arranged adjacent to the first edge E1 of the external memory device 100. Furthermore, according to an exemplary embodiment, the external input/output pins 30 may have a standardized arrangement to configure an interface between an external electronic device and electrical signals transmitted or received from or to the external memory device 100. For example, the external input/output pins 30 may have an arrangement standardized for parallel advanced technology attachment (ATA), serial ATA, eSATA, SAS, PCIe, optical fiber channel, SCSI, Gigabit Ethernet, or any other communication standards. The external memory device 100 will be described in more detail with reference to FIG. 4.

FIG. 4 is a sectional view of an external memory device according to an exemplary embodiment.

Referring to FIG. 4, an external memory device 100 includes a semiconductor integrated circuit (IC) device 10 formed on a semiconductor substrate 11.

According to an exemplary embodiment, the semiconductor substrate 11 may be formed of a single-crystal semiconductor material. For example, the semiconductor substrate 11 may be a silicon on insulator (SOI) substrate, a germanium substrate, a germanium on insulator (GOI) substrate, a silicon-germanium substrate, or a substrate of an epitaxial thin film obtained by performing selective epitaxial growth (SEG).

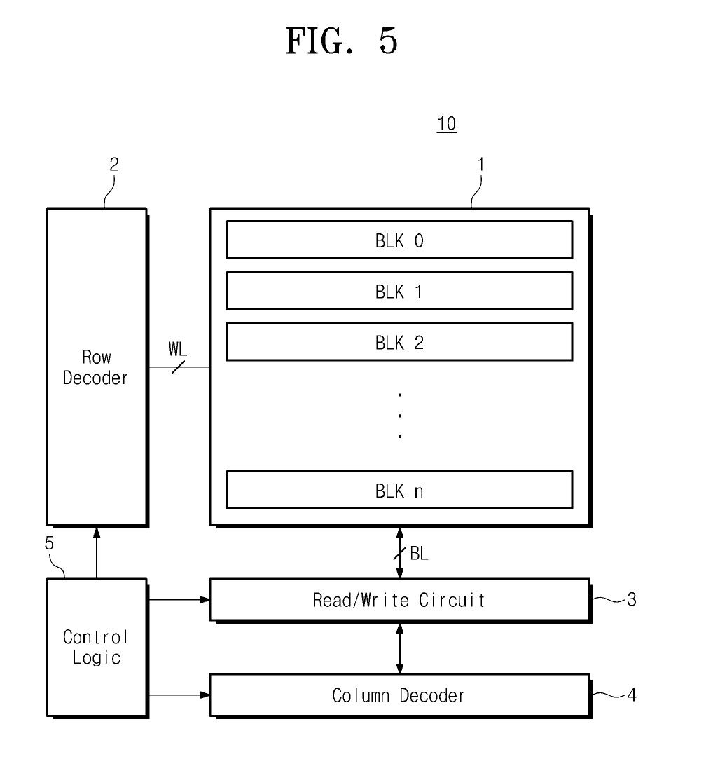

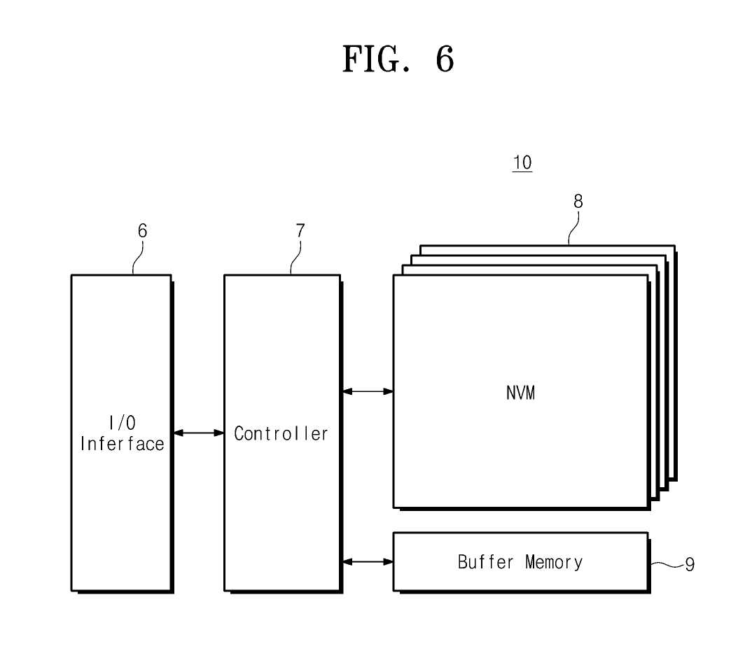

According to an exemplary embodiment, the semiconductor substrate 11 may have a first surface and a second surface facing each other. The semiconductor IC device 10 may be formed on the first surface of the semiconductor substrate 11. For example, the semiconductor IC device 10 may include MOS transistors, data storage components, and interconnections, which are formed on the first surface of the semiconductor substrate 11. The semiconductor IC device 10 formed on the semiconductor substrate 11 will be described in more detail with reference to FIGS. 5 and 6. At least one insulating layer 15 may be formed on the first surface of the semiconductor substrate 11 so as to cover the semiconductor IC device 10. Additionally, an insulating layer 15 may cover the second surface of the semiconductor substrate 11.

According to an exemplary embodiment, internal interconnections 40 connected to the semiconductor IC device 10 may be implemented in part as a through electrode. The through electrode 40 may penetrate the semiconductor substrate 11 and the insulating layer 15 to be electrically connected to the semiconductor IC device 10. The through electrode 40 may have a pillar shape and may include a barrier layer and a metallic layer. The barrier layer may include titanium, titanium nitride, tantalum, tantalum nitride, ruthenium, cobalt, manganese, tungsten nitride, nickel, nickel boride or a double layer such as titanium/titanium nitride, or a mixed layer having a different form from the double layer. The barrier layer may reduce the diffusion of a metal contained in the through electrode 40 to the semiconductor substrate 11. The metal layer may include silver (Ag), gold (Au), copper (Cu), aluminum (Al), tungsten (W), or indium (In). Additionally, a via insulating layer may be disposed between the through electrode 40, the semiconductor substrate 11, and the insulating layer 15. For example, the via insulating layer may include silicon oxide, silicon oxynitride, silicon nitride, or a combination thereof.

According to an exemplary embodiment, redistribution patterns 20 and external input/output pins 30 may be formed on the insulating layer 15 covering the second surface of the semiconductor substrate 11. The external input/output pins 30 may be connected to one end of the redistribution patterns 20 and the other end of the redistribution patterns 20 may be connected to the through electrodes 40.

According to an exemplary embodiment, the external input/output pins 30 may be formed through an electrolytic plating process, an electroless plating process, a CVD process, or a PVD process. For example, the external input/output pins 30 may be formed by plating a metallic material on portions of the redistribution patterns 20 exposed by a passivation layer 25. Accordingly, the external input/output pins 30 may be formed to be thicker than the redistribution patterns 20. According to an exemplary embodiment, the external input/output pins 30 may include a different metallic material than the redistribution patterns 20. For example, the redistribution patterns 20 may include a metallic nitride layer formed of titanium nitride, tantalum nitride, tungsten nitride, hafnium nitride, or zirconium nitride or a metallic layer formed of tungsten, copper, hafnium, zirconium, titanium, tantalum, aluminum, ruthenium, palladium, platinum, cobalt, or nickel.

The external input/output pins 30 may be formed of at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or a metallic alloy thereof. That is, the external input/output pins 30 may be formed of tin-silver (Sn—Ag), copper-nickel-lead (Cu—Ni—Pb), copper-nickel-gold (Cu—Ni—Au), copper-nickel (Cu—Ni), nickel-gold (Ni— Au), or nickel-silver (Ni—Ag), for example.

According to an exemplary embodiment, each of the external input/output pins 30 may include a first metal layer 31 and a second metal layer 33 sequentially stacked on the redistribution patterns 20. The second metal layer 33 may be exposed to an outside of external memory device 100 or may be in physically contact with an external electronic device. For example, the second metal layer 33 may be formed of noble metals such as gold (Au), silver (Ag), and platinum (Pt). Therefore, it is possible to prevent formation of native oxides on surfaces of the external input/output pins 30. The first metal layer 31 may be provided to reinforce stiffness of the second metal layer 33 formed of the noble metals. For example, the first metal layer 31 may be formed of nickel (Ni) or nickel alloy.

According to other exemplary embodiments, the redistribution patterns 20 and the external input/output pins 30 may be formed of the same conductive material.

According to an exemplary embodiment, the passivation layer 25 may cover the redistribution patterns 20 and expose the external input/output pins 30, so the external input/output pins 30 may be connected to an external electronic device. The passivation layer 25 may be formed of a silicon oxide layer, a silicon nitride layer, a silicon oxynitride layer, or an insulating material such as polyimide. In the case of a polyimide-based material such as photo sensitive polyimide (PSPI), the passivation layer 25 may be deposited through a spin coating process. Additionally, without the formation of an additional photoresist layer, a patterning process for forming an opening through an exposure process may be performed.

FIGS. 5 and 6 are block diagrams of a semiconductor integrated circuit device integrated into an external memory device according to an exemplary embodiment.

Referring to FIG. 5, a semiconductor integrated circuit (IC) device 10 includes a memory cell array 1, a row decoder 2, a read/write circuit 3, a column decoder 4, and a control logic 5.

The memory cell array 1 includes a plurality of memory blocks BLK0 to BLKn, and each of the memory blocks BLK0 to BLKn includes a plurality of memory cells and a plurality word lines and bit lines electrically connected to the memory cells.

The row decoder 2 selects one of the word lines by decoding an address inputted from the outside. The row decoder 2 is commonly connected to the plurality of memory blocks BLK0 to BLKn and provides a driving signal to the word lines of one selected from the memory blocks BLK0 to BLKn in response to a block selection signal. The row decoder 2 may provide a word line voltage generated from a voltage generation circuit (not shown) to each of a selected word line and unselected word lines in response to a control of a control circuit (not shown).

The read/write circuit 3 may temporarily store data to be stored in memory cells or may detect data stored in memory cells according to an operating mode. The read/write circuit 3 may operate as a write driver circuit during a program operating mode and may operate as a sense amplifier in a read operating mode. The read/write circuit 3 receives power (for example, voltage or current) from the control logic 5 and provides the received power to a selected bit line.

The column decoder 4 selects one of the bit lines by decoding an address inputted from the outside. The column decoder 4 is commonly connected to the plurality of memory blocks BLK0 to BLKn and provides data information to the bit lines of one selected from the memory blocks BLK0 to BLKn in response to a block selection signal. The column decoder 4 may provide a data transmission path between the read/write circuit 3 and an external device (for example, a memory controller).

According to an exemplary embodiment, the semiconductor IC device 10 may be a non-volatile memory device that is erasable and programmable electrically and retains data even when power is cut off. According to an exemplary embodiment, a NAND-type flash memory having a large capacity and a high speed storage capacity may be provided as a non-volatile memory device. As another example, the memory device may include PRAM, MRAM, ReRAM, FRAM, and NOR flash memory. Additionally, the memory device may be a volatile memory device that loses data when power is cut off, for example, DRAM and SRAM.

Referring to FIG. 6, the semiconductor IC device 10 includes an input/output interface 6, a controller 7, non-volatile memory devices 8, and a buffer memory 9.

The semiconductor IC device 10 may store or read data in or from the non-volatile memory devices 8 in response to a read/write request from an external electronic device. The semiconductor IC device 10 may exchange data with the external electronic device through the input/output interface 6. The input/output interface 6 may provide a physical connection of the external electronic device and the semiconductor IC device 10. In other words, the input/output interface 6 may interface with the semiconductor IC device 10 in response to a bus format of a host. The bus format of the host may be a Universal Serial Bus (USB), a peripheral component interconnection (PCI) express, a Serial ATA (SATA), or a Parallel ATA (PATA).

The controller 7 may connect the external electronic device and the non-volatile memory devices 8 through the input/output interface 6. The controller 7 may write data in the non-volatile memory devices 8 or may read data from the non-volatile memory devices 8 in response to a command provided from the external electronic device.

The non-volatile memory devices 8 may be implemented as, for example, a NAND-type flash memory having a large capacity and a high speed storage capacity. Alternatively, the non-volatile memory devices 8 may be implemented as, for example, PRAM, MRAM, ReRAM, FRAM, or NOR flash memory.

The buffer memory device 9 may temporarily store data that are transmitted or received between the non-volatile memory devices 8 and data that are transmitted or received between the controller 7 and a host. The buffer memory device 9 may be a random access memory such as DRAM or SRAM.

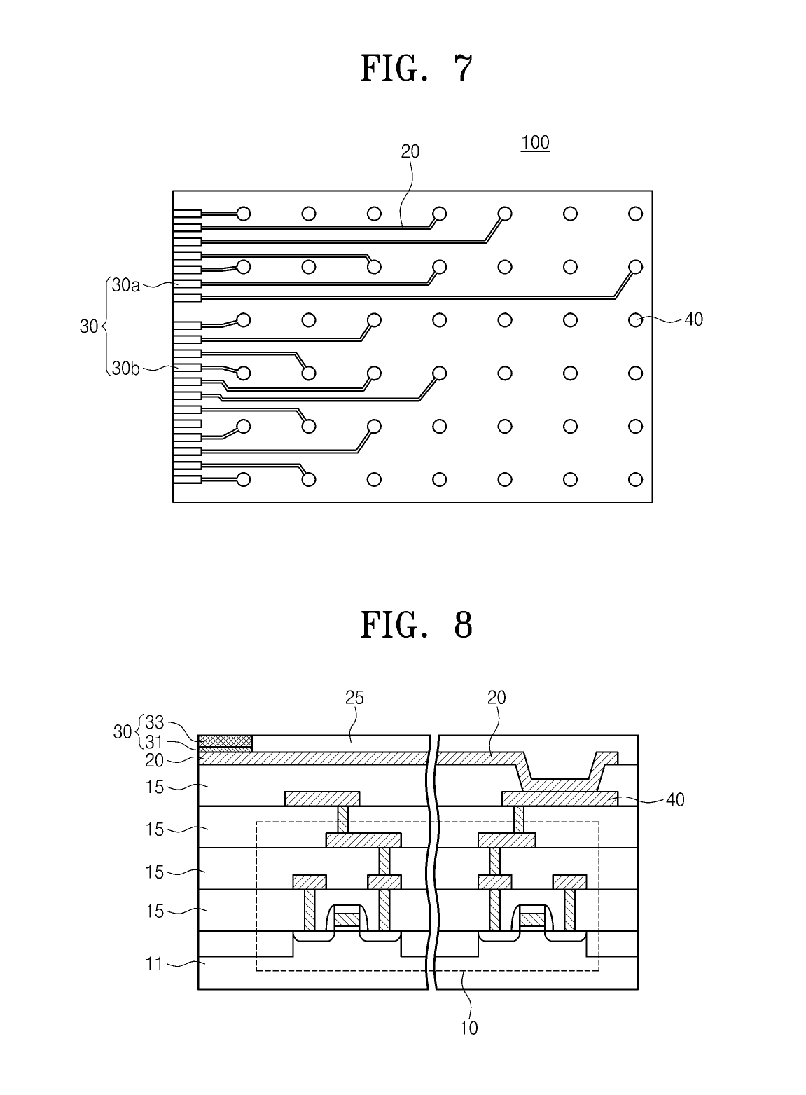

FIG. 7 is a plan view of an external memory device according to another exemplary embodiment. FIG. 8 is a sectional view of an external memory device according to another exemplary embodiment.

Referring to FIGS. 7 and 8, an external memory device 100 includes a semiconductor integrated circuit (IC) device 10 formed on a semiconductor substrate 11.

According to an exemplary embodiment, the semiconductor substrate 11 may be formed of a single-crystal semiconductor material. For example, the semiconductor substrate 11 may be a silicon on insulator (SOI) substrate, a germanium substrate, a germanium on insulator (GOI) substrate, a silicon-germanium substrate, and a substrate of an epitaxial thin film obtained by performing selective epitaxial growth (SEG).

According to an exemplary embodiment, the semiconductor integrated device 10 may be formed on the top surface of the semiconductor substrate 11. For example, the semiconductor IC device 10 may include MOS transistors, data storage components, and interconnections. As described with reference to FIG. 5, the semiconductor IC device 10 may include the memory cell array 1, the row decoder 2, the read/write circuit 3, the column decoder 4, and the control logic 5. Alternatively, as described with reference to FIG. 6, the semiconductor IC device 10 may include the input/output interface 6, the controller 7, the non-volatile memory devices 8, and the buffer memory 9.

At least one of insulating layers 15 may cover the semiconductor IC device 10 formed on the top surface of the semiconductor substrate 11. The insulating layer 15 may expose portions of internal interconnections 40 connected to the semiconductor IC device 10. The portions of the internal interconnections 40 exposed by the insulating layer 15 may be arranged two-dimensionally in a plan view.

Redistribution patterns 20 and external input/output pins 30 may be formed on the insulating layer 15. The external input/output pins 30 may be connected to one end of the redistribution patterns 20 and the other end of the redistribution patterns 20 may be connected to the internal interconnections 40 exposed by the insulating layer 15. According to an exemplary embodiment, the external input/output pins 30 may be formed to be thicker than the redistribution patterns 20. Also, the external input/output pins 30 may include a different metallic material than the redistribution patterns 20. Further, each of the external input/output pins 30 may include the first metal layer 31 and the second metal layer 33 sequentially stacked on the redistribution patterns 20, as described with reference to FIG. 4.

The passivation layer 25 may cover the redistribution patterns 20 on the insulating layer 15 and may expose the external input/output pins 30 to enable the external input/output pins 30 to be connected to an external electronic device.

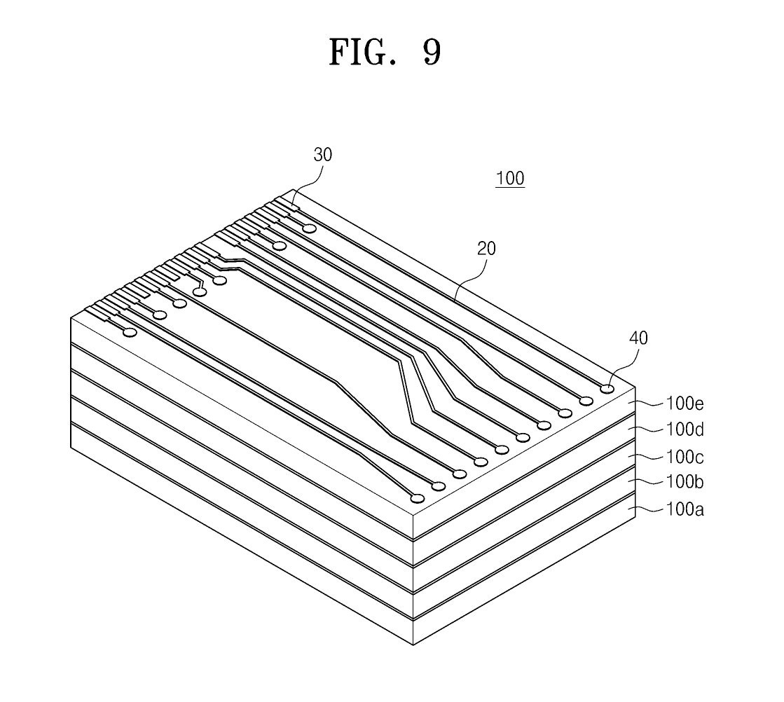

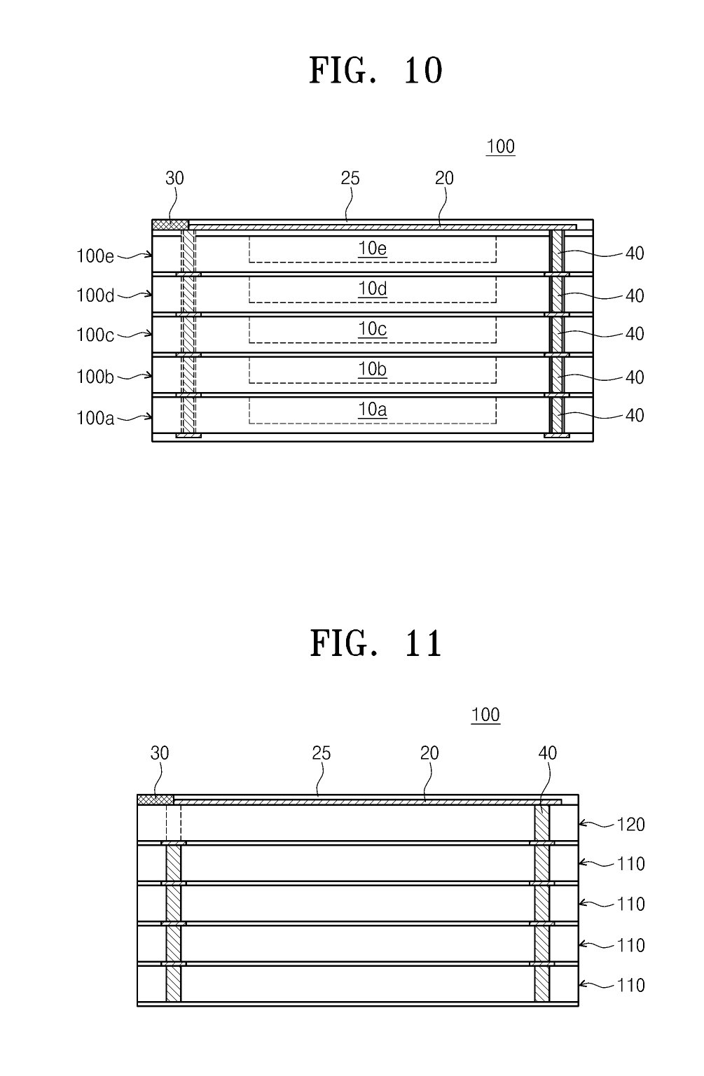

FIG. 9 is a perspective view of an external memory device according to another exemplary embodiment. FIG. 10 is a schematic sectional view of an external memory device according to another exemplary embodiment.

Referring to FIGS. 9 and 10, an external memory device 100 includes stacked first to fifth semiconductor devices 100a, 100b, 100c, 100d, and 100e. The stacked first to fifth semiconductor devices 100a to 100e may be electrically connected to each other via through electrodes 40. Additionally, the stacked first to fifth semiconductor devices 100a to 100e may adhere to each other by using an adhesive layer such as a direct adhesive film (DAF) or a film over wire (FOW).

In more detail, each of the first to fifth semiconductor devices 100a to 100e includes semiconductor IC devices 10a, 10b, 10c, 10d, and 10e formed on a semiconductor substrate and input/output pads connected to the semiconductor IC devices 10a to 10e. Input/output pads of the first to fifth semiconductor devices 100a to 100e may be electrically connected to each other via through electrodes 40.

According to an exemplary embodiment, the semiconductor IC devices 10a to 10e of the first to fifth semiconductor devices 100a to 100e may have the same operating characteristics. For example, the first to fifth semiconductor devices 100a to 100e may include a memory device or a logic device. Alternatively, the semiconductor IC devices 10a to 10e of the first to fifth semiconductor devices 100a to 100e may have different operating characteristics. For example, the semiconductor IC device 10a of the first semiconductor device 100a may include a buffer memory device; the semiconductor IC devices 10b and 10c of the second and third semiconductor devices 100b and 100c may include a non-volatile memory device; the semiconductor IC device 10d of the fourth semiconductor device 100 may include a controller or a microprocessor; and the semiconductor IC device 10e of the fifth semiconductor device 100e may include an input/output interface.

Furthermore, the uppermost fifth semiconductor device 100e may include the external input/output pins 30 connected to an external electronic device. In more detail, the fifth semiconductor device 100e may include redistribution patterns 20, external input/output pins 30, and a passivation layer 25. The redistribution patterns 20 may be formed on an insulating layer covering the semiconductor IC device 10e. The external input/output pins 30 may be connected to the redistribution patterns 20. The passivation layer 25 may cover the redistribution patterns 20 and expose portions of the external input/output pins 30. The external input/output pins 30 may include power input pins 30a and signal input/output pins 30b. Power provided from an external electronic device may be applied through the power input pins 30a. Electrical signals provided from an external device may be transmitted through the signal input/output pins 30b. Accordingly, the power and electrical signals provided from an external electronic device may be provided to the semiconductor IC devices 10a, 10b, 10c, 10d, and 10e through the external input/output pins 30 (see FIG. 2). In addition, as described above, the external input/output pins 30 may have a standardized arrangement to configure an interface between an external electronic device and electrical signals.

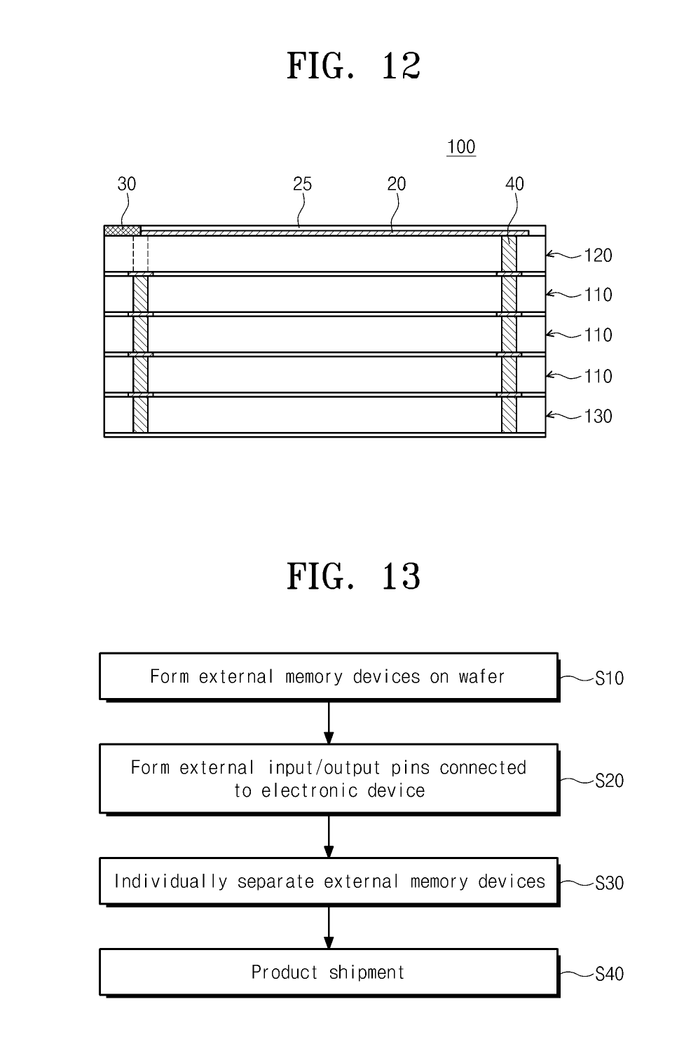

FIGS. 11 and 12 are sectional views of an external memory device according to various exemplary embodiments.

Referring to FIG. 11, an external memory device 100 may include a plurality of vertically-stacked semiconductor devices 110 and 120. According to an exemplary embodiment, each of the semiconductor devices 110 and 120 may store data provided from an external electronic device. For example, as described with reference to FIG. 5, each of the semiconductor devices 110 and 120 may include a memory cell array 1, a row decoder 2, a read/write circuit 3, a column decoder 4, and a control logic 5.

Referring to FIG. 12, an external memory device 100 may include a plurality of vertically-stacked semiconductor devices 110, 120, and 130. At least one semiconductor device (e.g., 130) among the plurality of semiconductor devices 110 to 130 may include a controller and the remaining semiconductor devices (e.g., 110 and 120) may include memory devices.

In the exemplary embodiments shown in FIGS. 11 and 12, the uppermost semiconductor device 120, as described above, may have the external input/output pins 30 connected to an external electronic device. Electrical signals inputted from an external electronic device through the external input/output pins 30 may be provided to the plurality of semiconductor devices 110 and 130 via the redistribution patterns 20 and through electrodes.

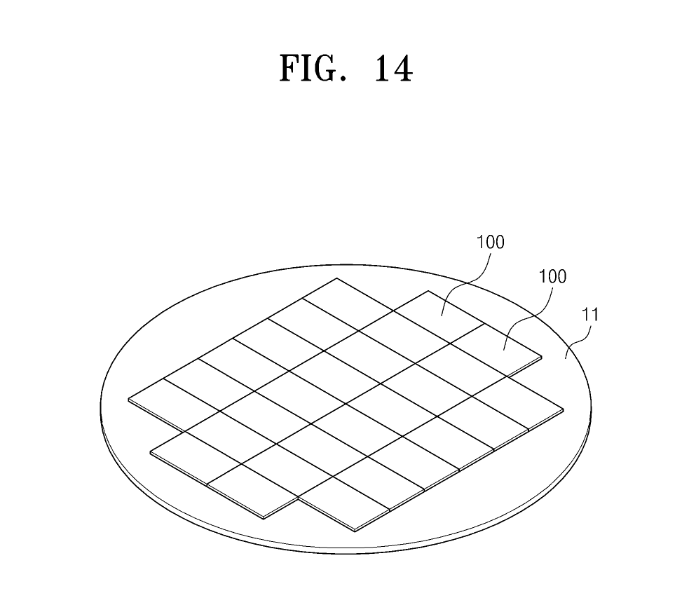

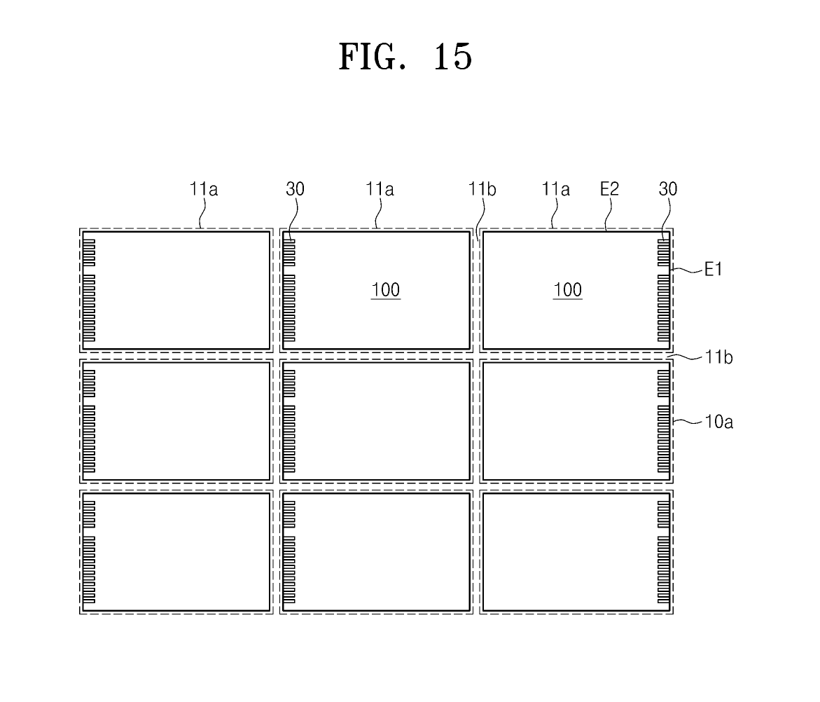

FIG. 13 is a flowchart illustrating a method of fabricating an external memory device according to an exemplary embodiment. FIGS. 14 to 15 are views illustrating a method of fabricating an external memory device according to an exemplary embodiment.

Referring to FIGS. 13, 14, and 15, a plurality of external memory devices 100 may be formed on a wafer 11 (e.g., a semiconductor substrate) at operation S10. The wafer 11 includes chip areas 11a arranged two-dimensionally and a scribe lane area 11b between the chip areas 11a. The external memory devices 100 may be formed in the chip areas 11a of the wafer 11, respectively.

According to an exemplary embodiment, the forming of the external memory devices 100 includes forming the semiconductor IC devices 10 (see FIG. 3) on the chip areas 11a of the wafer, forming the insulating layer 15 (see FIG. 4) covering the semiconductor IC devices 10, and forming the redistribution patterns 20 (see FIG. 3) connected to the semiconductor IC devices 10 on the insulating layer 15 and forming the passivation layer 25 of FIG. 3 covering the redistribution patterns 20 on the insulating layer 15. According to an exemplary embodiment, the semiconductor IC devices 10 may include memory devices and/or logic devices on the wafer 11 and interconnections connected thereto.

According to an exemplary embodiment, the redistribution patterns 20 and the external input/output pins 30 may be formed at the same time through a redistribution process. The redistribution patterns 20 may include a metallic nitride layer formed of titanium nitride, tantalum nitride, tungsten nitride, hafnium nitride, or zirconium nitride or a metallic layer formed of tungsten, copper, hafnium, zirconium, titanium, tantalum, aluminum, ruthenium, palladium, platinum, cobalt, or nickel.

The external input/output pins 30 (see FIG. 3) may be formed in each of the chip areas 11a at operation S20. The external input/output pins 30 may be formed on the wafer 11 having the semiconductor IC devices 10.

According to an exemplary embodiment, each of the chip areas 11a may include a first edge E1 and a second edge E2 perpendicular to each other and the external input/output pins 30 may be formed to be arranged adjacent to the first edge E1 of each of the chip areas 11a. Alternatively, the external input/output pins 30 may be arranged adjacent to the first and second edges E1 and E2, or in another configuration. Additionally, the external input/output pins 30 may have a standardized arrangement to enable an external electronic device to interface with electrical signals. According to an exemplary embodiment, the external input/output pins 30 may be arranged to enable an external electronic device to interface with data in SATA.

According to an exemplary embodiment, the external input/output pins 30 may be formed by performing an electrolytic plating process, an electroless plating process, a CVD process, or a PVD process. For example, the external input/output pins 30 may be formed by plating a metallic material on portions of the redistribution patterns 20 exposed by a passivation layer 25. The external input/output pins 30 may be formed to be thicker than the redistribution patterns 20. The external input/output pins 30 may include a different metallic material than the redistribution patterns 20. The external input/output pins 30 may be formed of at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or a metallic alloy thereof.

Furthermore, according to an exemplary embodiment, before the forming of the redistribution patterns 20 and the external input/output pins 30, the through electrodes 40 (see FIG. 3) may be formed. The through electrodes 40 may penetrate the wafer 11 and the insulating layers to connect to the redistribution patterns 20. Furthermore, according to an exemplary embodiment, before or after the forming of the external input/output pins 30, an electrical test process may be performed to detect defects of the semiconductor IC devices on the wafer 11.

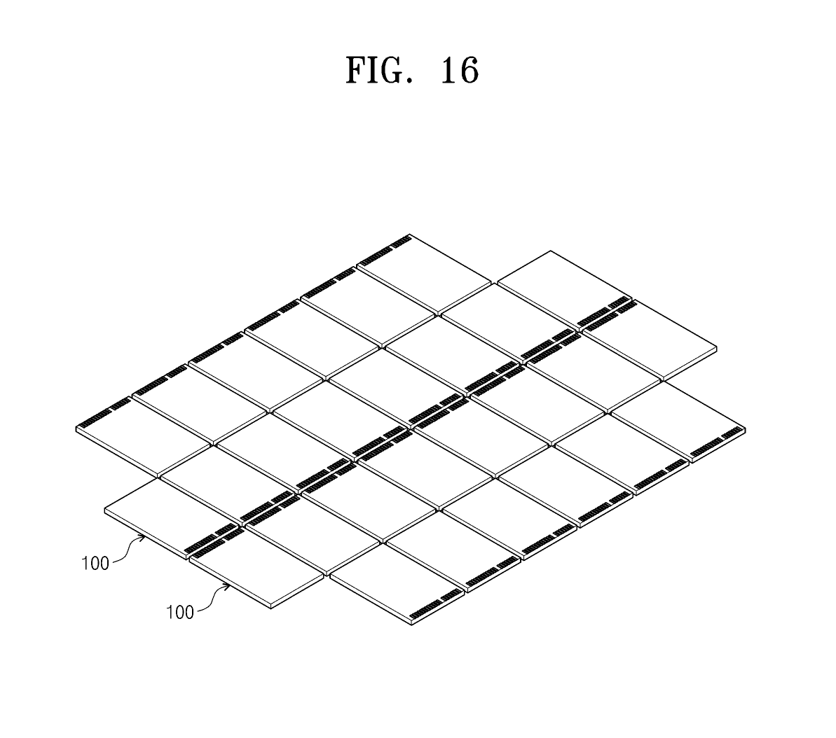

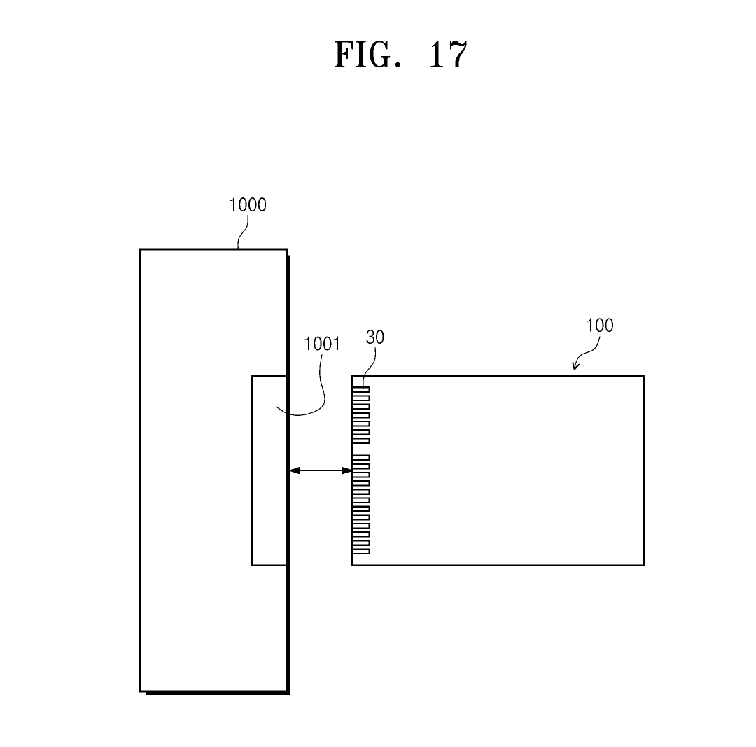

Next, referring to FIGS. 13 and 16, the external memory devices 100 formed on the wafer 11 may be individually separated by cutting the wafer 11 along the scribe lane area 11b at operation S30.

Finally, each of the external memory devices 100 may be shipped out without performing a packaging process, and then each of the external memory devices 100 may be installed in an electronic device (e.g., personal computers or mobile devices) at operation S40. According to exemplary embodiments, when each of the external memory devices 100 is installed in the electric device, the external input/output pins 30 may be physically and electrically connected to the electric device.

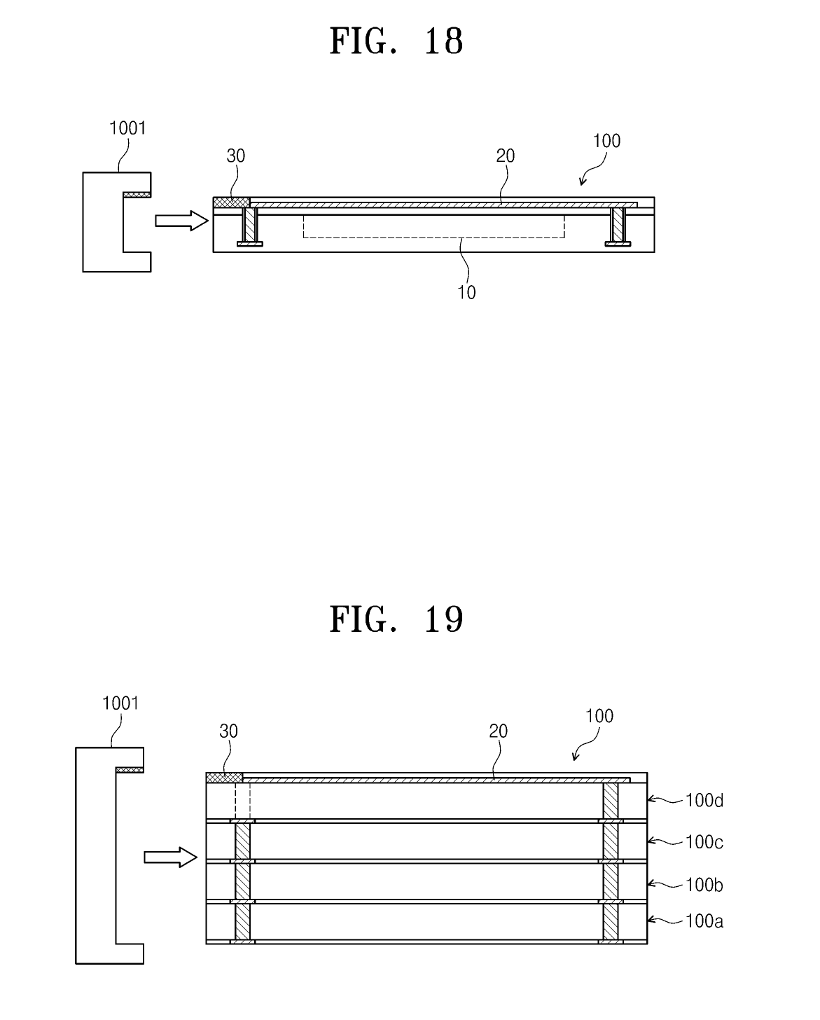

FIG. 17 is a block diagram illustrating a connection between an external memory device and an electronic device according to an exemplary embodiment. FIGS. 18 and 19 are views illustrating a connection between an external memory device and an electronic device according to exemplary embodiments.

Referring to FIGS. 17, 18, and 19, a host 1000 includes at least one connector 1001 having a plurality of input/output terminals. According to an exemplary embodiment, the external memory device 100 is electrically connected to the host 1000 through external input/output pins 30, so that the external memory device 100 may provide an additional storage space to the host 1000. The external memory device 100 may operate in response to a request from the host 1000 and stores or reads data for the host 1000.

The host 1000 provides requests to write data to or read date from the external memory device 100 through the external input/output pins 30. The host 1000 may be a data processing device, such as a personal computer (PC), a portable computer, and a smart TV, a video player, a DVD player, a portable multimedia player (PMP), a portable DVD player, or a mobile phone.

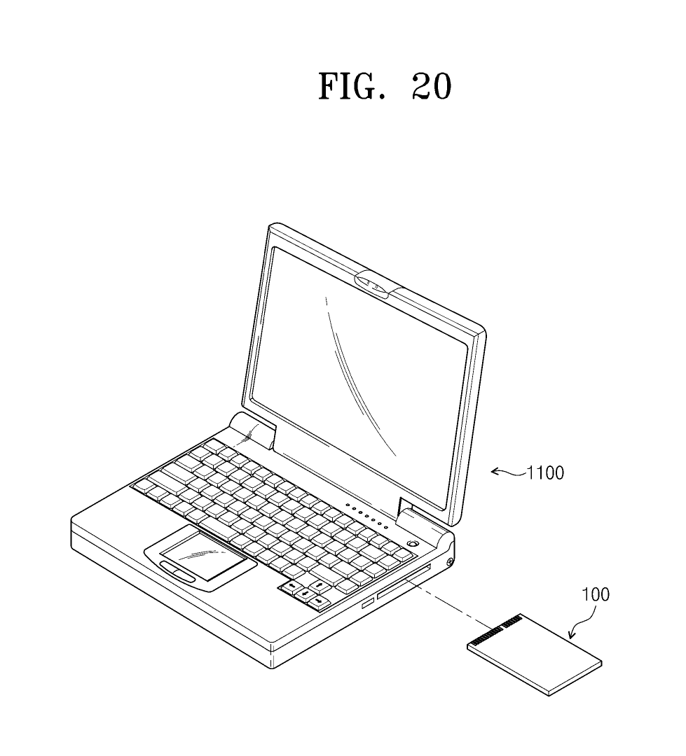

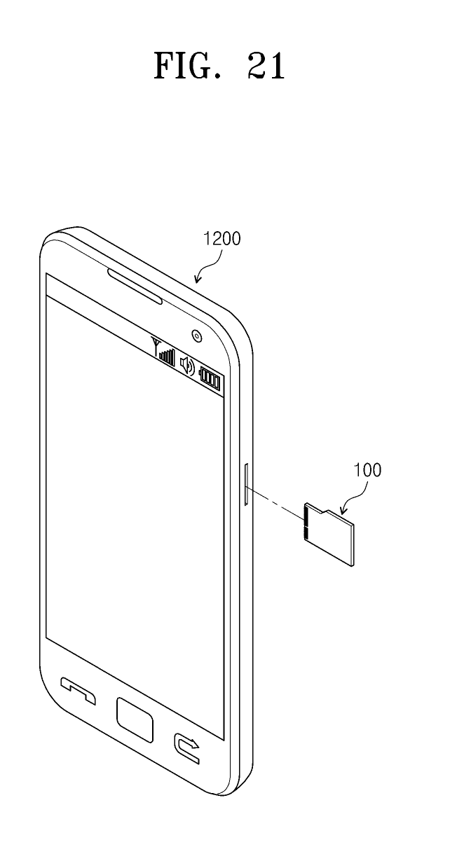

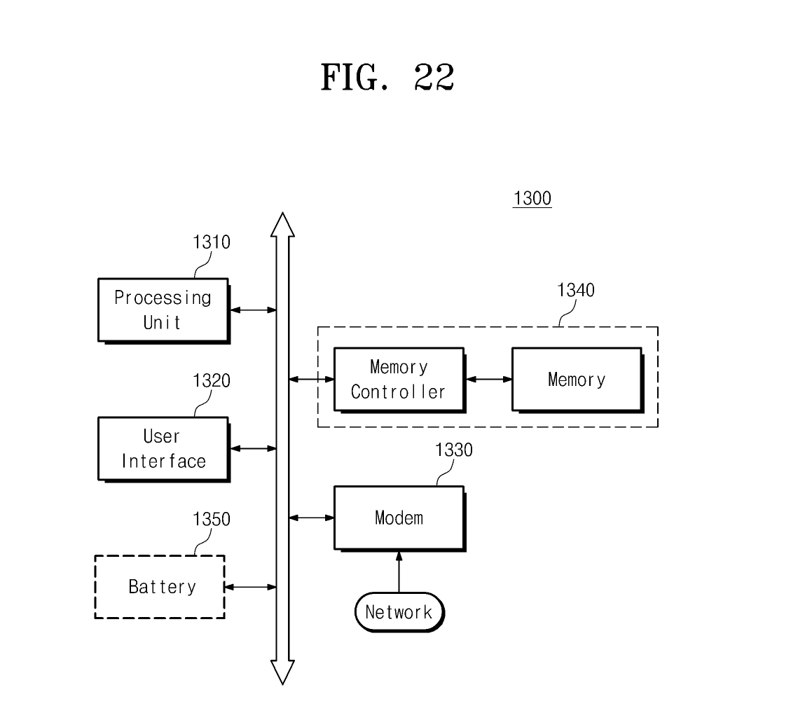

FIGS. 20 and 21 are views illustrating electronic devices to which an external memory device is applied according to exemplary embodiments. The external memory device 100 may be applied to a PDA, a portable computer, a web tablet, a wireless phone, a mobile phone, a digital music player, and many other types of devices capable of transmitting and/or receiving information in a wireless environment.

Referring to FIG. 20, the external memory device 100 may be mounted in a portable computer 1100. In more detail, a space where the external memory device 100 is inserted may be provided to the portable computer 1100. External input/output pins of the external memory device 100 may be directly connected to a host communication port (not shown) equipped in the portable computer 1100.

The external memory device 100 connected to the portable computer 1100 may write and/or read data to and/or from a semiconductor integrated circuit (IC) device equipped in the external memory device 100 in response to a data write/read command from the portable computer 1100.

Referring to FIG. 21, the external memory device 100 may be mounted in a mobile phone 1200. In more detail, a space where the external memory device 100 is mounted may be provided to the mobile phone 1200. External input/output pins of the external memory device 100 may be directly connected to a host communication port (not shown) equipped in the mobile phone 1200. The external memory device 100 connected to the mobile phone 1200 may provide an additional storage space to the mobile phone 1200 in response to a command from the mobile phone 1200.

FIG. 22 is a block diagram of an electronic system including an external memory device according to an exemplary embodiment.

Referring to FIG. 22, an electronic system 1300 may include at least one semiconductor package according to at least one of the exemplary embodiments. The electronic system 1300 may include a mobile device or a computer. For example, the electronic system 1300 may include a processor 1310, a user interface 1320, an external memory device 1340 according to at least one of the exemplary embodiments, and a modem 1330 such as a baseband chipset. Each of the components in the electronic system 1300 may exchange data with each other via a bus. The processor 1310 may execute a program and control the electronic system 1300. The user interface 1320 may be used for inputting or outputting data to the electronic system 1300. The external memory device 1340 may store codes for operations of the processor 1310, data processed by the processor 1310, or data inputted from the outside. The external memory device 1340 may include a memory controller and a memory.

The electronic system 1300 may be realized with a mobile system, a personal computer, an industrial computer, or a logic system performing various functions. When the electronic system 1300 is a mobile system, a battery 1350 for supplying an operating voltage of an electronic device may be additionally provided. For example, the mobile system may be one of a personal digital assistant (PDA), a portable computer, a web tablet, a mobile phone, a wireless phone, a laptop computer, a memory card, a digital music system, and an information transmitting and/or receiving system. When the electronic system 1300 is implemented as equipment for performing wireless communication, the electronic system 1300 may use many different types of communication interface protocols, such as, for example, CDMA, GSM, NADC, E-TDMA, WCDAM, and CDMA2000.

According to exemplary embodiments, external input/output pins of an external memory device may be formed on a wafer together with semiconductor IC devices. Accordingly, after external memory devices respectively formed on chip areas of a wafer are separated individually, each of the external memory devices of a wafer level may be mounted on an external electronic device without needing to perform an additional packaging process. That is, the size of an external memory device may be reduced and the manufacturing time and cost of an external memory device may be also reduced.

The above-disclosed description of the exemplary embodiments is to be considered illustrative and not restrictive, and the appended claims are intended to cover all such modifications, enhancements, and other exemplary embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. An external memory device configured to communicate with an external electronic device, the external memory device comprising:
a semiconductor substrate comprising a first edge and a second edge perpendicular to the first edge;
a semiconductor integrated circuit device provided on the semiconductor substrate, the semiconductor integrated circuit device comprising a memory device configured to store data provided from the external electronic device, an input/output interface configured to interface with the external electronic device, and a controller configured to control the memory device in response to a signal transmitted through the input/output interface;
an insulating layer covering the semiconductor integrated circuit device; and
external input/output pins provided adjacent to the first edge on the insulating layer and configured to establish an electrical connection between the external electronic device and the semiconductor integrated circuit device.

2. The external memory device of claim 1, further comprising:
interconnections connecting the external input/output pins to the semiconductor integrated circuit device, the interconnections being provided on the insulating layer; and
a passivation layer covering the interconnections provided on the insulating layer and exposing portions of the external input/output pins to enable the external input/output pins to directly connect to the external electronic device.

3. The external memory device of claim 2, further comprising through electrodes penetrating the semiconductor substrate and the insulating layer to connect the interconnections and the semiconductor integrated circuit device.

4. The external memory device of claim 2, wherein the external input/output pins and the interconnections are provided on a top surface of the insulating layer and a thickness of the external input/output pins is greater than a thickness of the interconnections.

5. The external memory device of claim 2, wherein the external input/output pins comprise a metallic material different from a metallic material of the interconnections.

6. The external memory device of claim 1, wherein the semiconductor substrate is a silicon substrate, a germanium substrate, a silicon-germanium substrate, a silicon on insulator (SOI) substrate, a germanium on insulator (GOI) substrate, or a semiconductor epitaxial substrate.

7. The external memory device of claim 1, wherein the external input/output pins comprise power input pins into which power is inputted from the external electronic device and signal input/output pins through which electrical signals are inputted from or outputted to the external electronic device.

8. The external memory device of claim 1, wherein the external input/output pins are configured to exchange data with the external electronic device in a serial advanced technology attachment (ATA) scheme.

9. An external memory, comprising:
a substrate;
a semiconductor integrated circuit (IC) provided on the substrate;
a passivation layer covering a portion of the semiconductor IC; and
an external pin provided adjacent to a side of the passivation layer, the external pin being exposed to an outside of the external memory and configured to establish an electrical connection between the semiconductor IC and an external electronic device,
wherein the external pin physically contacts the external electronic device.

10. The external memory of claim 9, wherein the external pin comprises a first metal layer and a second metal layer on the first metal layer, and the second metal layer is exposed to the outside of the external memory.

11. The external memory of claim 10, wherein the second metal layer comprises noble metals.

12. The external memory of claim 9, wherein the substrate comprises a single-crystal semiconductor material.

13. The external memory of claim 9, wherein the semiconductor IC comprises:
a memory device configured to store data provided from the external electronic device;
an input/output interface configured to interface with the external electronic device; and
a controller configured to control the memory device in response to a signal transmitted through the input/output interface.

14. The external memory of claim 9, further comprising:
a redistribution pattern comprising a first end connected to the external pin; and
a through electrode connected to a second end of the redistribution pattern and further connected to the semiconductor IC.

15. The external memory of claim 9, wherein the external pin comprises power input pins into which power is inputted from the external electronic device and signal input/output pins through which electrical signals are inputted from or outputted to the external electronic device.

16. An external memory, comprising:
a substrate;
a semiconductor integrated circuit (IC) provided on the substrate;
a passivation layer covering a portion of the semiconductor IC; and
an external pin provided adjacent to a side of the passivation layer, the external pin being exposed to an outside of the external memory and configured to establish an electrical connection between the semiconductor IC device and an external electronic device.

17. The external memory of claim 16, further comprising:
a redistribution pattern comprising a first end connected to the external pin; and
a through electrode connected to a second end of the redistribution pattern and further connected to the semiconductor IC.

18. The external memory of claim 16, wherein the external pin is thicker than the redistribution pattern.

19. The external memory of claim 16, wherein the semiconductor IC comprises a non-volatile memory device.

20. The external memory of claim 16, wherein the substrate comprises a single-crystal semiconductor material.
